(19) United States
(12) Patent Application Publication
(10) Pub. No.: US 2025/0269496 A1
(43) Pub. Date: Aug. 28, 2025

(54) LIGHT WEIGHT HIGH STIFFNESS CHUCK WITH INTERCHANGEABLE TOP

(71) Applicant: KLA Corporation, Milpitas, CA (US)

(72) Inventors: Lim Chow Tian, Singapore (SG); Rajeev Patil, Fremont, CA (US); Hingkuong Wong, Singapore (SG); Jayan Jinson, Singapore (SG)

(21) Appl. No.: 18/587,311

(22) Filed: Feb. 26, 2024

(51) Int. Cl. B25B 11/00; B25J 11/00; H01L 21/683

(52) U.S. Cl. CPC B25B 11/005; B25J 11/0095; H01L 21/6838

(57) ABSTRACT

An apparatus for securing a substrate includes a detachable plate configured to reversibly attach to a base of a chuck. One or more portions of a common fluidic pathway are shared for receiving air (e.g., purging air), and for a formation of a first vacuum seal and a second vacuum seal. The base of the chuck includes one or more base-substrate inlet channels and one or more base-plate inlet channels. The detachable plate includes one or more first reservoirs and second reservoirs and is configured to establish a fluidic connection between the one or more first reservoirs and the base-plate inlet channels for forming a first vacuum seal between the detachable plate and the base. The detachable plate includes pass-through channels for fluidic connection with the one or more second reservoirs for forming a second vacuum seal between the detachable plate and a substrate.

### TECHNICAL FIELD

The present disclosure generally relates to a substrate chucking system and, more particularly, to a substrate chucking system with a vacuum-held, detachable top plate.

### BACKGROUND

As tolerances on semiconductor device fabrication processes continue to narrow, the demand for improved optical systems for semiconductor wafer review continues to increase. In such an optical system, a substrate chuck may be used to secure a substrate in place. Traditionally, in order to review multiple shapes, sizes, and varieties of substrates, multiple substrate chucks have to be interchanged. The process of interchanging substrate chucks and properly calibrating multiple substrate chucks can often take a long period of time. Further, fabrication of multiple substrate chucks can be costly. Moreover, purging to remove contaminants may be time consuming and use costly equipment.

Therefore, it would be desirable to provide a system and method that cure the shortfalls of the previous approaches identified above.

### SUMMARY

An apparatus for securing a substrate is disclosed, in accordance with one or more embodiments of the present disclosure. In one embodiment, the apparatus includes a detachable plate configured for reversible attachment to a base of a chuck. In another embodiment, the detachable plate includes one or more first reservoirs on a backside portion of the detachable plate and one or more second reservoirs on a frontside portion of the detachable plate. In another embodiment, the base includes one or more base-substrate inlet channels and one or more base-plate inlet channels. In another embodiment, the detachable plate is configured to establish fluidic connection between the one or more first reservoirs on the backside portion of the detachable plate and the one or more base-plate inlet channels for forming a first vacuum seal between the detachable plate and the base. In another embodiment, the detachable plate includes one or more pass-through channels for fluidic connection with the one or more base-substrate inlet channels to establish fluidic connection between the one or more second reservoirs on the frontside portion of the detachable plate for forming a second vacuum seal between the detachable plate and the substrate. In another embodiment, the one or more base-substrate inlet channels and the one or more base-plate inlet channels are configured for receiving air via fluidic connection with an air supply sub-system. In another embodiment, one or more portions of a common fluidic pathway are shared for the receiving of the air, and for the formation of the first vacuum seal, and for the formation of the second vacuum seal.

In one aspect, the air supply sub-system includes an air purge sub-system configured to purge an environment around the substrate.

An apparatus for securing a substrate is disclosed, in accordance with one or more embodiments of the present disclosure. In one embodiment, the apparatus includes a base of a chuck. In another embodiment, the apparatus includes an air supply sub-system fluidically coupled to one or more base-substrate inlet channels and one or more base-plate inlet channels configured for receiving air. In another embodiment, the air supply sub-system is configured for providing the air. In another embodiment, the apparatus includes a detachable plate. In another embodiment, the detachable plate is configured for reversible attachment to the base of the chuck. In another embodiment, the detachable plate includes one or more first reservoirs on a backside portion of the detachable plate and one or more second reservoirs on a frontside portion of the detachable plate. In another embodiment, the base includes the one or more base-substrate inlet channels and the one or more base-plate inlet channels. In another embodiment, the detachable plate is configured to establish fluidic connection between the one or more first reservoirs on the backside portion of the detachable plate and the one or more base-plate inlet channels for forming a first vacuum seal between the detachable plate and the base. In another embodiment, the detachable plate includes one or more pass-through channels for fluidic connection with the one or more base-substrate inlet channels to establish fluidic connection between the one or more second reservoirs on the frontside portion of the detachable plate for forming a second vacuum seal between the detachable plate and the substrate.

A method is disclosed, in accordance with one or more embodiments of the present disclosure. In one embodiment, the method includes receiving a detachable plate including one or more first reservoirs on a backside portion of the detachable plate and one or more second reservoirs on a frontside portion of the detachable plate. In another embodiment, the method includes securing the detachable plate to a base of a chuck by establishing fluidic connection between the one or more first reservoirs on the backside portion of the detachable plate and one or more base-plate inlet channels to form a first vacuum seal between the detachable plate and the base. In another embodiment, the method includes receiving a substrate. In another embodiment, the method includes purging an environment proximate to the substrate via an air supply sub-system fluidically coupled to the one or more base-substrate inlet channels and the one or more base-plate inlet channels, wherein the air supply sub-system is configured for providing the air. In another embodiment, the method includes securing the substrate to the detachable plate by establishing fluidic connection, via one or more pass-through channels, between the one or more base-substrate inlet channels and the one or more second reservoirs on the frontside portion of the detachable plate to form a second vacuum seal between the detachable plate and the substrate.

It is to be understood that both the foregoing general description and the following detailed description are exemplary and explanatory only and are not necessarily restrictive of the invention as claimed. The accompanying drawings, which are incorporated in and constitute a part of the specification, illustrate embodiments of the invention and together with the general description, serve to explain the principles of the invention.

### BRIEF DESCRIPTION OF THE DRAWINGS

The numerous advantages of the disclosure may be better understood by those skilled in the art.

FIG. 1 illustrates a cross-sectional view of a substrate chucking sub-system, in accordance with one or more embodiments of the present disclosure.

FIG. 2 illustrates an exploded assembly view of a substrate chucking sub-system, in accordance with one or more embodiments of the present disclosure.

FIG. 3A illustrates a top view of a detachable plate, in accordance with one or more embodiments of the present disclosure.

FIG. 3B illustrates a bottom view of a detachable plate, in accordance with one or more embodiments of the present disclosure.

FIG. 4 illustrates a process flow diagram of a method for chucking of a substrate, in accordance with one or more embodiments of the present disclosure.

### DETAILED DESCRIPTION

The present disclosure has been particularly shown and described with respect to certain embodiments and specific features thereof. The embodiments set forth herein are taken to be illustrative rather than limiting. It should be readily apparent to those of ordinary skill in the art that various changes and modifications in form and detail may be made without departing from the spirit and scope of the disclosure. Reference will now be made in detail to the subject matter disclosed, which is illustrated in the accompanying drawings.

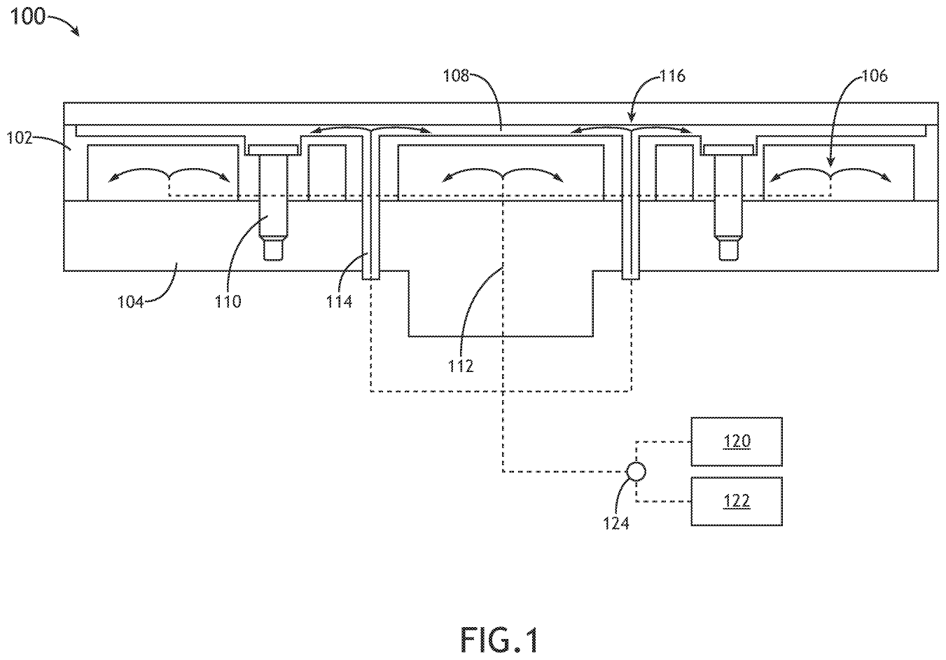

Referring generally to FIGS. 1 through 4, a system and method for a substrate-chucking system is described, in accordance with one or more embodiments of the present disclosure.

Embodiments of the present disclosure are directed to a substrate-chucking system with a vacuum-secured, detachable top plate suitable for quick interchange on a chuck base and shared flow paths for the vacuum function and a purge function (e.g., clean dry air (CDA) purge). Such a configuration reduces the number of components and occupies less volume in the substrate chuck interchanging process, as it allows for common flow paths.

A wafer chuck with a vacuum holding interchangeable top plate is described in U.S. Patent Publication Number 2023/0069384, published on Mar. 2, 2023, entitled QUICK SWAP CHUCK WITH VACUUM HOLDING INTERCHANGEABLE TOP PLATE, which is incorporated herein by reference in its entirety.

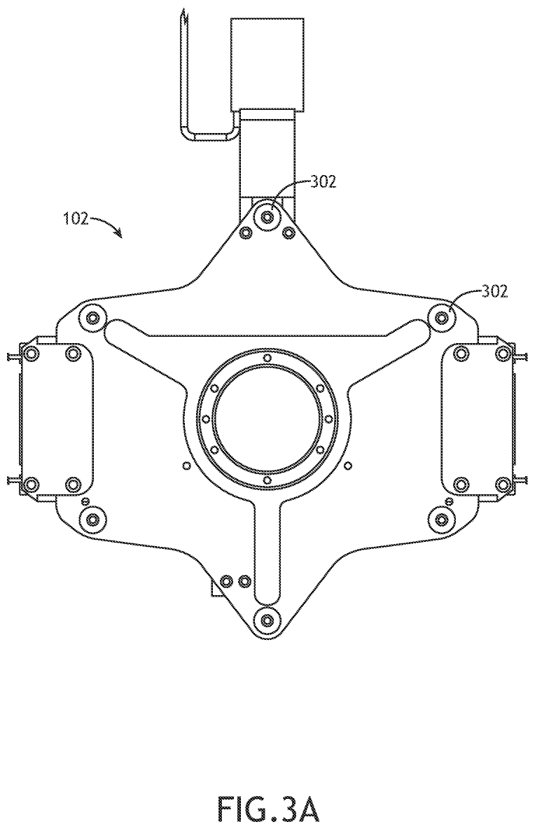

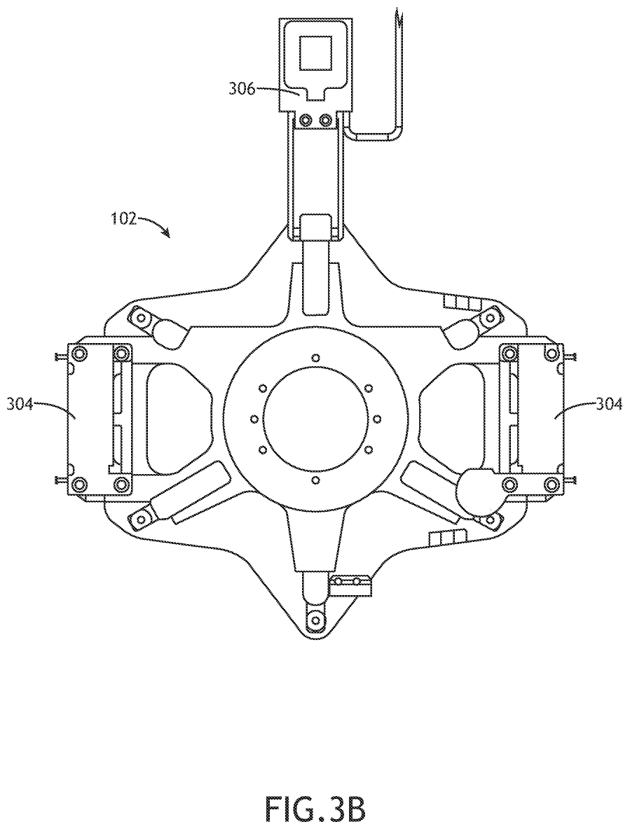

FIG. 1 illustrates a cross-sectional view of a substrate chucking sub-system, in accordance with one or more embodiments of the present disclosure. In embodiments, the substrate chucking sub-system 100 includes a chuck base 104, a detachable plate 102, one or more upper inlets 114 (e.g., base-substrate inlet channels 114), one or more lower inlets 112 (e.g., base-plate inlet channels 112), an upper reservoir 108, one or more lower reservoirs 106, and one or more fasteners 110 for securing a substrate 116 to the detachable plate 102. In embodiments, chuck base 104 may be mechanically coupled to a rotational drive unit (e.g., see rotational unit 306 in FIG. 3B). For example, chuck base 104 may be coupled to a rotational drive unit, wherein the rotational drive unit is configured to rotate the chuck base 104, the detachable plate 102, and the substrate 116 during an optical system process (e.g., inspection, metrology, and lithography).

In embodiments, the detachable plate 102 includes one or more lower reservoirs 106 located on the bottom side portion of the detachable plate 102 and on the top side portion of chuck base 104. In this regard, the detachable plate 102 is attached to the chuck base 104 using the one or more lower reservoirs 106. For example, during operation, a fluidic connection may be established between one or more lower inlets 112 and one or more lower reservoirs 106 to create a vacuum seal between detachable plate 102 and chuck base 104. In this regard, the vacuum seal established using the one or more lower reservoirs 106 and the one or more lower inlets 112 serves to provide a downward force on detachable plate 102, sealing and holding the bottom side of detachable plate 102 to the top side of chuck base 104.

In embodiments, detachable plate 102 may be secured to chuck base 104 using one or more fasteners 110. The one or more fasteners 110 may include any fastening elements known in the art, including, but not limited to, screws, bolts, and pins. In embodiments, detachable plate 102 may be formed from materials including, but not limited to, of polyetheretherketone polymer, carbon fiber, or silicon carbide. In embodiments, detachable plate 102 may be coated with one or more coatings. For example, detachable plate 102 may be coated with one or more layers of anti-reflective coating.

In embodiments, the detachable plate 102 includes one or more top reservoirs 108. In this regard, substrate 116 (e.g., a semiconductor wafer) may be attached to the detachable plate 102 using the one or more top reservoirs 108, which are located on the bottom side of substrate 116 and on the top side of detachable plate 102. For example, a fluidic connection may be established between one or more upper inlets 114 and one or more upper reservoirs 108 to create a vacuum seal between detachable plate 102 and substrate 116. In this regard, the vacuum seal established using the one or more upper reservoirs 108 and the one or more upper inlets 114 serves to provide a downward force on substrate 116, sealing and holding the bottom side of substrate 116 to the top side of detachable plate 102.

In embodiments, the upper inlets 114 and the lower inlets 112 share a common fluidic connection pathway for both achieving the vacuums above and below the detachable plate 102 as well as for an air purge. At least one or more portions of the common fluidic pathway (e.g., at least some length of the inlet channels, coupling orifices, and/or the like) are shared for the receiving of the air (purging air), for the formation of the first vacuum seal, and for the formation of the second vacuum seal. For example, any number of valves and the like may be used to redirect air or to allow a vacuum in one or more areas. For instance, the portions of the common fluidic pathway may include all or part of the upper inlets 114 and the lower inlets 112.

Sharing the fluidic connections may reduce the number of components, occupy less space, reduce costs, and the like. For example, the upper inlets 114 and the lower inlets 112 may form a fluidic connection with (or be configured for such a connection with) both a vacuum sub-system 120 and an air supply sub-system 122. The common fluidic connection pathway may, but is not necessarily required to, fluidically connect using one or more valves 124 to the vacuum sub-system 120 and the air supply sub-system 122. For instance, after a purging step, the valve 124 may switch flow connection from the air supply sub-system 122 to the vacuum sub-system 120.

In embodiments, the upper inlets 114 and the lower inlets 112 receive air using a fluidic connection with the air supply sub-system 122. For example, substrate chucking sub-system 100 may include the air supply sub-system 122, which may include a compressor, air dryer, set of filters, and/or the like. For instance, the air supply sub-system 122 may include (or be) an air purge sub-system configured to purge an environment around the substrate 116. The air supply sub-system 122 may be configured to condition air (e.g., air stored in a container), such as removing oil and/or other particulates from the air. For example, the air may be clean dry air (CDA). Clean Dry Air (CDA) refers to compressed air that has been treated to remove moisture, oil, particulates, and other contaminants to a level that meets specific industry standards, particularly for sensitive environments such as those found in the semiconductor industry. The quality of CDA may be categorized by the international standard ISO 8573-1:2010, which defines different classes of air purity based on the concentration of contaminants. The air may be conditioned to be Class 0 CDA. To condition the air to be CDA, the air supply sub-system 122 may include an oil-free air compressor, a desiccant dryer to remove moisture to a low pressure dew point (PDP), and one or more stages of filters to eliminate particulates and other contaminants. The PDP may be below −70° Celsius to ensure that no moisture is present in the compressed air. This level of dryness may aide in preventing corrosion, contamination, and other issues that could compromise the manufacturing process or damage sensitive equipment.

In embodiments, the upper inlets 114 and the lower inlets 112 may be configured to create the vacuum seals described herein using a fluidic connection with the vacuum sub-system 120. For example, the substrate chucking sub-system 100 (e.g., apparatus) may include the vacuum sub-system 120, which may include a vacuum pump and/or the like configured to pull air out of an enclosed volume. For example, the vacuum sub-system 120 may remove the air used to purge the environment around the substrate 116. For example, the vacuum sub-system 120 used to remove the purging air may be the same or a different vacuum sub-system used to create the vacuum seals disclosed herein. In this way, the common fluidic connection pathway may allow for supplying air for purging, removing the air with a vacuum, and generating the vacuum seals with a vacuum.

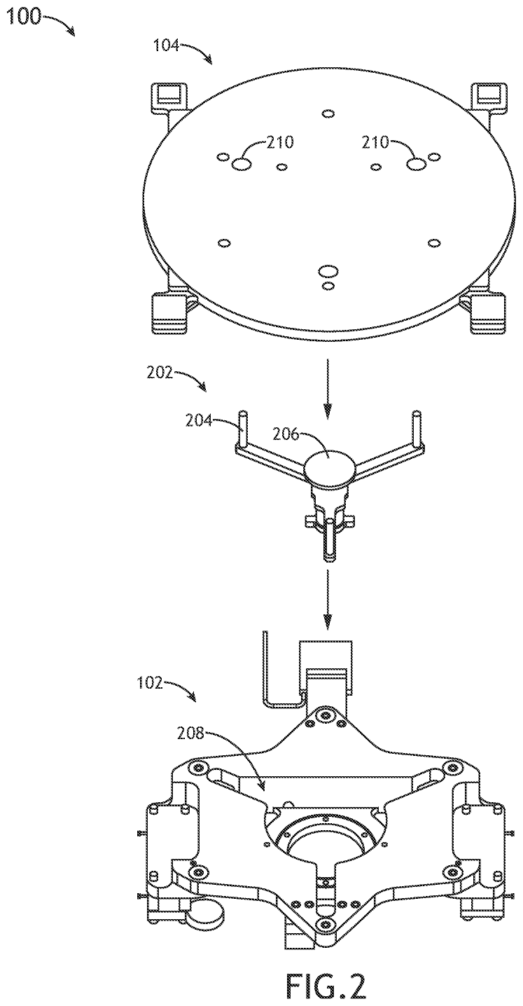

FIG. 2 illustrates an exploded assembly view of a substrate chucking sub-system, in accordance with one or more embodiments of the present disclosure.

In embodiments, a shim 202 may be used to adjust for a variety of substrate thicknesses, such as a range of 1000 microns or more in thickness adjustment. The shim 202 may be disposed between the base 104 and the detachable plate 102. A shim body 206 may include one or more vertical members 204. For instance, the vertical members 204 may be interchangeable using different sizes to accommodate different substrate thicknesses. The shim 202 may contact the substrate by passing through voids 210 in the detachable plate 102, such as the vertical members 204 passing through the voids 210. The base 104 may include a recess 208 configured to receive and support the shim 202.

FIG. 3A illustrates a top view of a detachable plate, in accordance with one or more embodiments of the present disclosure. The fasteners 110 of FIG. 1 may be used to secure the detachable plate 102 to mounts 302 of the base 104.

FIG. 3B illustrates a bottom view of a detachable plate, in accordance with one or more embodiments of the present disclosure. In embodiments, brake pads 304 may be coupled to the base 104. For example, a brake pad 304 may be coupled to each side of the base 104.

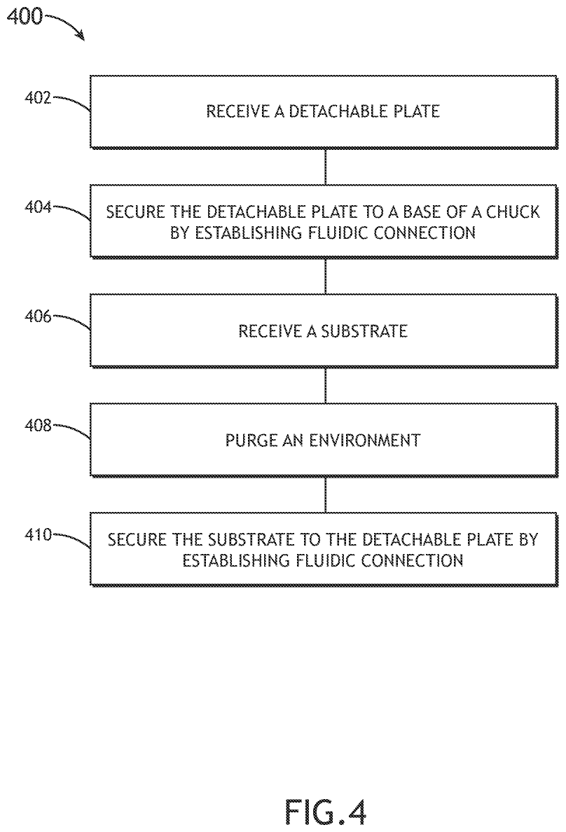

FIG. 4 illustrates a process flow diagram of a method 400 for chucking of a wafer using an interchangeable wafer plate, in accordance with one or more embodiments of the present disclosure. It is noted herein that the steps of method 400 may be implemented all or in part by sub-system 100. It is further recognized, however, that the method 400 is not limited to the sub-system 100 in that additional or alternative system-level embodiments may carry out all or part of the steps of method 400.

In a step 402, a detachable plate is received. In embodiments, as shown in FIG. 1, the upper inlets 114 and the lower inlets 112 are configured for receiving air via fluidic connection with the air supply sub-system 122 (e.g., CDA purge sub-system), and where common fluidic pathways are shared with a vacuum sub-system 120 and the air supply sub-system 122. The detachable plate 102 includes reservoirs on the bottom and top portions of the detachable plate. For example, detachable plate 102 may include one or more upper reservoirs 108 on the top portion of detachable plate 102 and one or more lower reservoirs 106 on the bottom portion of detachable plate 102.

In a step 404, the detachable plate is secured to the chuck base by establishing fluidic connection between the lower reservoirs on the bottom portion of the detachable plate and the lower inlets to form a vacuum seal between the detachable plate and the chuck base. For example, as illustrated by FIG. 1, a fluidic connection may be established between one or more lower inlets 112 and one or more lower reservoirs 106 to create a vacuum seal between detachable plate 102 and chuck base 104. In this regard, the vacuum seal established using the one or more lower reservoirs 106 and the one or more lower inlets 112 serves to provide a downward force on detachable plate 102, sealing and holding the bottom side of detachable plate 102 to the top side of chuck base 104.

In a step 406, a substrate 116 is received. For example, a semiconductor wafer, a transparent glass wafer, or the like may be received.

In a step 408, an environment is purged. For example, one or more areas may be desired to be purged with air to remove airborne molecular contaminants and maintain silicon wafers in an inert environment. For instance, the sub-system 100 and/or the substrate 116 may be purged with air (e.g., CDA) using the air supply sub-system 122. Purging may be performed in an enclosure, such as inside an isolation chamber that includes the sub-system 100 and substrate 116. The air for purging may be removed using one or more vacuum sub-systems 120.

In a step 410, the substrate is secured to the detachable plate by establishing fluidic connection between the upper inlets and the upper reservoirs on the top portion of the detachable plate to form a vacuum seal between the top portion of the detachable plate and the lower portion of the substrate. For example, as illustrated in FIG. 1, a fluidic connection may be established between one or more upper inlets 114 and one or more upper reservoirs 108 to create a vacuum seal between detachable plate 102 and substrate 116. In this regard, the vacuum seal established using the one or more upper reservoirs 108 and the one or more upper inlets 114 serves to provide a downward force on substrate 116, sealing and holding the bottom side of substrate 116 to the top side of detachable plate 102.

One skilled in the art will recognize that the herein described components, devices, objects, and the discussion accompanying them are used as examples for the sake of conceptual clarity and that various configuration modifications are contemplated. Consequently, as used herein, the specific exemplars set forth and the accompanying discussion are intended to be representative of their more general classes. In general, use of any specific exemplar is intended to be representative of its class, and the non-inclusion of specific components, devices, and objects should not be taken as limiting.

Those having skill in the art will appreciate that there are various vehicles by which processes and/or systems and/or other technologies described herein can be affected (e.g., hardware, software, and/or firmware), and that the preferred vehicle will vary with the context in which the processes and/or systems and/or other technologies are deployed. For example, if an implementer determines that speed and accuracy are paramount, the implementer may opt for a mainly hardware and/or firmware vehicle; alternatively, if flexibility is paramount, the implementer may opt for a mainly software implementation; or, yet again alternatively, the implementer may opt for some combination of hardware, software, and/or firmware. Hence, there are several possible vehicles by which the processes and/or devices and/or other technologies described herein may be affected, none of which is inherently superior to the other in that any vehicle to be utilized is a choice dependent upon the context in which the vehicle will be deployed and the specific concerns (e.g., speed, flexibility, or predictability) of the implementer, any of which may vary.

The previous description is presented to enable one of ordinary skill in the art to make and use the invention as provided in the context of a particular application and its requirements. As used herein, directional terms such as “top,” “bottom,” “over,” “under,” “upper,” “upward,” “lower,” “down,” and “downward” are intended to provide relative positions for purposes of description and are not intended to designate an absolute frame of reference. Various modifications to the described embodiments will be apparent to those with skill in the art, and the general principles defined herein may be applied to other embodiments. Therefore, the present invention is not intended to be limited to the particular embodiments shown and described but is to be accorded the widest scope consistent with the principles and novel features herein disclosed.

With respect to the use of substantially any plural and/or singular terms herein, those having skill in the art can translate from the plural to the singular and/or from the singular to the plural as is appropriate to the context and/or application. The various singular/plural permutations are not expressly set forth herein for sake of clarity.

All the methods described herein may include storing results of one or more steps of the method embodiments in memory. The results may include any of the results described herein and may be stored in any manner known in the art. The memory may include any memory described herein or any other suitable storage medium known in the art. After the results have been stored, the results can be accessed in the memory and used by any of the method or system embodiments described herein, formatted for display to a user, used by another software module, method, or system, and the like. Furthermore, the results may be stored “permanently,” “semi-permanently,” temporarily,” or for some period of time. For example, the memory may be random access memory (RAM), and the results may not necessarily persist indefinitely in the memory.

It is further contemplated that each of the embodiments of the method described above may include any other step(s) of any other method(s) described herein. In addition, each of the embodiments of the method described above may be performed by any of the systems described herein.

The herein described subject matter sometimes illustrates different components contained within, or connected with, other components. It is to be understood that such depicted architectures are merely exemplary, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “connected,” or “coupled,” to each other to achieve the desired functionality, and any two components capable of being so associated can also be viewed as being “couplable,” to each other to achieve the desired functionality. Specific examples of couplable include but are not limited to physically mateable and/or physically interacting components and/or wirelessly interactable and/or wirelessly interacting components and/or logically interacting and/or logically interactable components.

Furthermore, it is to be understood that the invention is defined by the appended claims. It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” and the like). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to inventions containing only one such recitation, even when the same claim includes the introductory phrases “one or more” or “at least one” and indefinite articles such as “a” or “an” (e.g., “a” and/or “an” should typically be interpreted to mean “at least one” or “one or more”); the same holds true for the use of definite articles used to introduce claim recitations. In addition, even if a specific number of an introduced claim recitation is explicitly recited, those skilled in the art will recognize that such recitation should typically be interpreted to mean at least the recited number (e.g., the bare recitation of “two recitations,” without other modifiers, typically means at least two recitations, or two or more recitations). Furthermore, in those instances where a convention analogous to “at least one of A, B, and C, and the like” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, and the like). In those instances where a convention analogous to “at least one of A, B, or C, and the like” is used, in general such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, and the like). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

It is believed that the present disclosure and many of its attendant advantages will be understood by the foregoing description, and it will be apparent that various changes may be made in the form, construction, and arrangement of the components without departing from the disclosed subject matter or without sacrificing all of its material advantages. The form described is merely explanatory, and it is the intention of the following claims to encompass and include such changes. Furthermore, it is to be understood that the invention is defined by the appended claims.

What is claimed:

1. An apparatus for securing a substrate comprising:
a detachable plate, wherein the detachable plate is configured for reversible attachment to a base of a chuck, wherein the detachable plate includes one or more first reservoirs on a backside portion of the detachable plate and one or more second reservoirs on a frontside portion of the detachable plate,
wherein the base includes one or more base-substrate inlet channels and one or more base-plate inlet channels,
wherein the detachable plate is configured to establish fluidic connection between the one or more first reservoirs on the backside portion of the detachable plate and the one or more base-plate inlet channels for forming a first vacuum seal between the detachable plate and the base,
wherein the detachable plate includes one or more pass-through channels for fluidic connection with the one or more base-substrate inlet channels to establish fluidic connection between the one or more second reservoirs on the frontside portion of the detachable plate for forming a second vacuum seal between the detachable plate and the substrate, and
wherein the one or more base-substrate inlet channels and the one or more base-plate inlet channels are configured for receiving air via fluidic connection with an air supply sub-system, wherein one or more portions of a common fluidic pathway are shared for the receiving of the air, and for the formation of the first vacuum seal, and for the formation of the second vacuum seal.

2. The apparatus of claim 1, wherein the air supply sub-system comprises an air purge sub-system configured to purge an environment around the substrate.

3. The apparatus of claim 1, wherein the detachable plate is secured to the base via one or more fasteners.

4. The apparatus of claim 1, wherein the detachable plate is secured to the base via the first vacuum seal between the detachable plate and the base.

5. The apparatus of claim 1, wherein the detachable plate is coated with one or more coatings.

6. The apparatus of claim 5, wherein the one or more coatings comprise one or more anti-reflective coatings.

7. The apparatus of claim 1, wherein at least a portion of the detachable plate is formed from at least one of polyetheretherketone polymer, carbon fiber, or silicon carbide.

8. The apparatus of claim 1, wherein the base of the chuck is mechanically coupled to a rotational drive unit, wherein the rotational drive unit comprises:
a spindle; and
a motor.

9. The apparatus of claim 1, wherein the substrate comprises:
a semiconductor wafer.

10. An apparatus for securing a substrate comprising:
a base of a chuck;
an air supply sub-system fluidically coupled to one or more base-substrate inlet channels and one or more base-plate inlet channels configured for receiving air, wherein the air supply sub-system is configured for providing the air;
a detachable plate, wherein the detachable plate is configured for reversible attachment to the base of the chuck, wherein the detachable plate includes one or more first reservoirs on a backside portion of the detachable plate and one or more second reservoirs on a frontside portion of the detachable plate,
wherein the base includes the one or more base-substrate inlet channels and the one or more base-plate inlet channels,
wherein the detachable plate is configured to establish fluidic connection between the one or more first reservoirs on the backside portion of the detachable plate and the one or more base-plate inlet channels for forming a first vacuum seal between the detachable plate and the base, and
wherein the detachable plate includes one or more pass-through channels for fluidic connection with the one or more base-substrate inlet channels to establish fluidic connection between the one or more second reservoirs on the frontside portion of the detachable plate for forming a second vacuum seal between the detachable plate and the substrate.

11. A method comprising:
receiving a detachable plate including one or more first reservoirs on a backside portion of the detachable plate and one or more second reservoirs on a frontside portion of the detachable plate;
securing the detachable plate to a base of a chuck by establishing fluidic connection between the one or more first reservoirs on the backside portion of the detachable plate and one or more base-plate inlet channels to form a first vacuum seal between the detachable plate and the base;
receiving a substrate;
purging an environment proximate to the substrate via an air supply sub-system fluidically coupled to the one or more base-substrate inlet channels and the one or more base-plate inlet channels, wherein the air supply sub-system is configured for providing the air; and
securing the substrate to the detachable plate by establishing fluidic connection, via one or more pass-through channels, between the one or more base-substrate inlet channels and the one or more second reservoirs on the frontside portion of the detachable plate to form a second vacuum seal between the detachable plate and the substrate.

12. The method of claim 11, further comprising:
conditioning the air, before the purging, wherein the conditioning of the air comprises removing contaminates from the air.

13. The method of claim 11, wherein the air supply sub-system comprises an air purge sub-system configured to purge an environment around the substrate.

14. The method of claim 11, wherein the detachable plate is secured to the base via one or more fasteners.

15. The method of claim 14, herein the one or more fasteners comprise at least one of one or more screws, one or more bolts, or one or more pins.

16. The method of claim 11, wherein the detachable plate is secured to the base via the first vacuum seal between the detachable plate and the base.

17. The method of claim 11, wherein the detachable plate is coated with one or more coatings.

18. The method of claim 17, wherein the one or more coatings comprise one or more anti-reflective coatings.

19. The method of claim 11, wherein the base of the chuck is mechanically coupled to a rotational drive unit, wherein the rotational drive unit comprises:
a spindle; and
a motor.

20. The method of claim 11, wherein the substrate comprises:
a semiconductor wafer.
